(19) United States
(12) Patent Application Publication
(10) Pub. No.: US 2017/0032235 A1
(43) Pub. Date: Feb. 2, 2017

(54) SCANNER RESISTANT DEVICE WITH BUILT IN READING LENS AND LED LIGHT

(71) Applicants: Eric Cohen, Miami, FL (US); Victor Lee, Chino Hills, CA (US)

(72) Inventors: Eric Cohen, Miami, FL (US); Victor Lee, Chino Hills, CA (US)

(21) Appl. No.: 14/810,213

(22) Filed: Jul. 27, 2015

(51) Int. Cl. G06K 19/073; H05K 9/00; G02B 27/02

(52) U.S. Cl. CPC G06K 19/07327; G02B 27/025; H05K 9/0007

(57) ABSTRACT

A device for protecting one or more credit or charge cards from radio frequency scanning is disclosed. The device comprises a layered planar element sized for fitting within a card slot of a personal carrying accessory, wherein the planar element is composed of an uncharged, conductive material and wherein the planar element inhibits the transmission of radio frequency signals. The planar element also has a front and back plastic layer for the addition of other items. In particular, a reading lens and a push button activated light source are integrated with the front plastic layer for easing reading of small text and in low lighting conditions.

### CROSS-REFERENCE TO RELATED APPLICATIONS

Not Applicable.

### STATEMENT REGARDING FEDERALLY SPONSORED RESEARCH OR DEVELOPMENT

Not Applicable.

### INCORPORATION BY REFERENCE OF MATERIAL SUBMITTED ON A COMPACT DISC

Not Applicable.

### FIELD OF THE INVENTION

Most broadly, the invention relates to the field of electronic commerce; more particularly, it is directed to a device protecting portable items from unwanted scanning using radio frequency electromagnetic waves.

### BACKGROUND OF THE INVENTION

Radio-frequency identification (RFID) is a technology that uses radio waves to transfer data from an electronic tag, called an RFID tag or label, attached to an object, through a reader for the purpose of identifying and tracking the object. RFID technology has been used for many applications, including key entry cards, passports, road toll fee payments, identification cards, and cash transaction cards, such as credit and charge cards. RFID technology typically includes embedding a card or device with a microchip that stores certain information, such as passwords, identifiers, personal information or records of user transactions. The technology has become so popular, that many credit card issuers have started using RFID technology as a replacement for traditional magnetic strip credit cards.

Passive RFID tags (those without a battery) can be read if passed within close enough proximity to an RFID reader or scanner. It is not necessary to “show” the tag to the reader or scanner device, as with a bar code. In other words it does not require line of sight to “see” an RFID tag, the tag can be read inside a wallet, purse, case, carton, box or other container, and unlike barcodes, RFID tags can be read hundreds at a time. Some RFID tags can be read from several meters away and beyond the line of sight of the reader.

RFID technology, however, has come with drawbacks. The private information stored on RFID cards are easier targets for potential identity thieves and “electronic pickpockets.” A potential identity thief or electronic pickpocket can use an RFID scanner to read the private information stored on an RFID card, even when it is stored in a wallet, purse or pocket. The potential thief needs only to hold a handheld RFID scanner in close proximity to the wallet or purse in order to read the private information contained in the RFID card. This has caused concern in the financial and security industries.

Consequently, a need exists to overcome the problems with the prior art as discussed above, and particularly for a more efficient way of protecting the data on RFID cards.

### SUMMARY OF THE INVENTION

Briefly, according to an embodiment, a device for preventing radio frequency scanning of a card is disclosed. The device comprises a layered planar element sized for fitting within a card slot of a personal carrying accessory, wherein the planar element is composed of an uncharged, conductive material and wherein the planar element inhibits the transmission of radio frequency signals. The planar element also has a front and back plastic layer for the addition of other items. In particular, a reading lens and a push button activated light source are integrated with the front plastic layer for easing reading of small text and in low lighting conditions.

The foregoing and other features and advantages of the disclosed embodiments will be apparent from the following more particular description of the preferred embodiments, as illustrated in the accompanying drawings.

### BRIEF DESCRIPTION OF THE DRAWINGS

The subject matter, which is regarded as the invention, is particularly pointed out and distinctly claimed in the claims at the conclusion of the specification. The foregoing and other features and also the advantages of the disclosed embodiments will be apparent from the following detailed description taken in conjunction with the accompanying drawings.

FIG. 1A presents a perspective view of credit cards placed between two scanner resistant devices in one embodiment. FIG. 1B presents a front elevation view of credit cards placed between two scanner resistant devices in one embodiment.

FIG. 2 presents a front cross section view of a wallet having credit cards placed between two scanner resistant devices in one embodiment.

FIG. 3 presents a cross section perspective view of the three layer structure of a scanner resistant device in one embodiment.

FIG. 4A presents a front elevation view of a reading lens retracted into its built in holder of the scanner resistant device in one embodiment. FIG. 4B presents a front elevation view of a reading lens being deployed out of its built in holder of the scanner resistant device in one embodiment.

FIG. 5 presents a front elevation view of a reading lens being deployed out of its built in holder of the scanner resistant device in one embodiment; this view particularly shows the curved surface of the holder.

FIG. 6 presents a front elevation view of a reading lens being deployed out of its built in holder of the scanner resistant device in one embodiment; this view also shows a built in button for actuating LED lights also built into the scanner resistant device.

FIG. 7A presents the reading lens device fully removed from the scanner resistant device in one embodiment. FIG. 7B presents the reading lens partially deployed from or partially retracted into the scanner resistant device in one embodiment. FIG. 7C presents the reading lens device fully retracted into the scanner resistant device in one embodiment.

FIG. 8A presents the reading lens device fully removed from the scanner resistant device in one embodiment. FIG. 8B presents the reading lens device partially deployed from or partially retracted into the scanner resistant device in one embodiment. FIG. 8C presents the reading lens device fully retracted into the scanner resistant device in one embodiment.

Like reference numerals refer to like parts throughout the several views of the drawings.

### DETAILED DESCRIPTION

The following detailed description is merely exemplary in nature and is not intended to limit the described embodiments or the application and uses of the described embodiments. As used herein, the word “exemplary” or “illustrative” means “serving as an example, instance, or illustration.” Any implementation described herein as “exemplary” or “illustrative” is not necessarily to be construed as preferred or advantageous over other implementations. All of the implementations described below are exemplary implementations provided to enable persons skilled in the art to make or use the embodiments of the disclosure and are not intended to limit the scope of the disclosure, which is defined by the claims. For purposes of description herein, the terms “upper”, “lower”, “left”, “rear”, “right”, “front”, “vertical”, “horizontal”, and derivatives thereof shall relate to the invention as oriented in each figure. Furthermore, there is no intention to be bound by any expressed or implied theory presented in the preceding technical field, background, brief summary or the following detailed description. It is also to be understood that the specific devices and processes illustrated in the attached drawings, and described in the following specification, are simply exemplary embodiments of the inventive concepts defined in the appended claims. Hence, specific dimensions and other physical characteristics relating to the embodiments disclosed herein are not to be considered as limiting, unless the claims expressly state otherwise.

The disclosed embodiments solve the problems with the prior art by providing a small, inexpensive and lightweight device that prevents surreptitious scanning of RFID cards and that can be placed within an existing personal carrying case, such as a wallet, purse, handbag, holder or other type of carrying device. RFID cards that may be protected include credit cards, charge cards, identification cards, security tokens, pass cards, entry cards, passports, badges, etc. The disclosed embodiments are advantageous since they allow for the use of existing personal carrying cases and do not require the purchase of new carrying cases that prevent scanning. The disclosed embodiments are further advantageous since they are manufactured from lightweight, durable material that remains effective for extended periods of time.

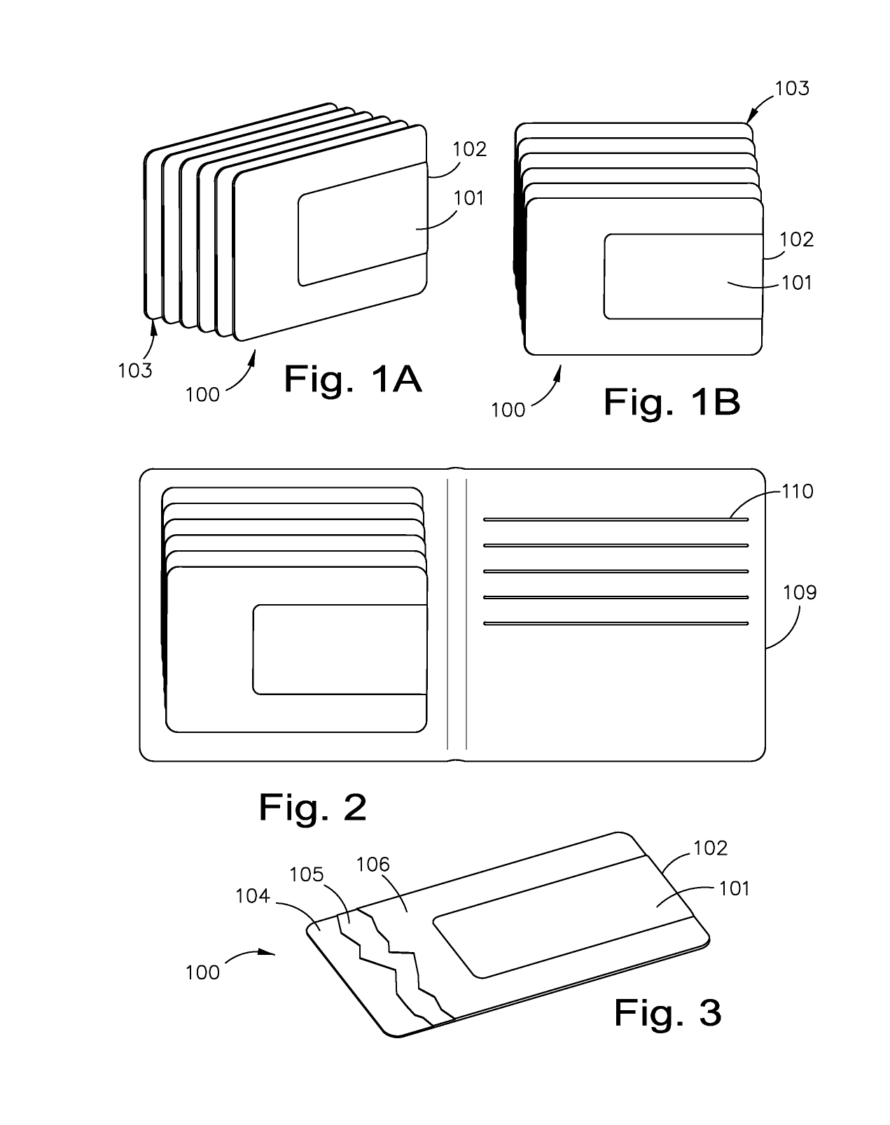

In order to prevent an electronic thief from accessing data stored on a card, a user can carry the device 100 (see FIG. 1) in his or her wallet thereby limiting or even neutralizing the possibility of the theft. Thus, information stored on credit or debit cards, drivers licenses and passports are thereby protected from theft. Further, the addition of a reading lens in the wallet facilitates the reading of items that are too small to read. Finally, bright light emitting diode (LED) lights built into the device 100 helps users to read during low lighting conditions. Thus, the embodiments taught herein can prevent all RFID cards from being read by unwanted electronic pickpockets as well as providing visual aids for both poor lighting and small text conditions.

Most generally, the scanner resistant device 100 taught herein is a three layer longitudinal planar element sized as a typical credit card. The first layer is a plastic material (PVC, PET, ABS) for typical backing and printing purposes followed by a second layer of metallic material; this is made of suitable metals such as aluminum, copper, nickel, chrome, etcetera). The third layer is a plastic material (PVC, PET, ABS) for backing and also for holding a removable reading lens that can be placed back into its holder in the scanner resistant device. Said plastic of the first and third layers may or may not cover some or all of the sides of the device 100. In one embodiment, there is no first and third layer, but rather only a second layer comprising the metallic material.

It should be understood that the first and the third layer may be integral along the peripheral edges so as to encapsulate the metallic layer there between. The reading lens is made from a clear polycarbonate (PC or equivalent). An optional embodiment herein disclosed has one or more LED reading light disposed upon the surface of the third layer actuated by a plastic button integrated with the same and in wired communication with a battery power source. Thus, a user is provided with a RFID scanner resistant device having a reading lens to magnify small difficult to read text and a lighting device to assist in reading during low lighting conditions.

The scanner resistant device 100 taught herein has an uncharged, conductive material, such as a dielectric metal or metal alloy as its central layer. Alternative materials include aluminum, steel, iron, tin, copper, chromium, nickel, brass and stainless steel. In another alternative, the central layer or ‘blocker device’ is composed of a metallic foil material layer, such as aluminum foil, that is laminated or covered on both sides with a layer of plastic material, such as PVC or ABS plastic forming two further layers as disclosed herein previously.

It should be readily understood that a laminate is a material that can be constructed by uniting two or more layers of material together. The process of creating a laminate is lamination, which in common parlance refers to the placing of something between layers of plastic and gluing them with heat, pressure and or an adhesive. The laminating process may be pouch lamination or heated roll lamination. In one embodiment of the present invention, each scanner resistant device includes printed information, such as advertising, logos, artwork, promotional materials or contact information, on at least one of its outer layers' external surfaces.

In one embodiment, each scanner resistant device 100 is manufactured using a stamping process. Stamping includes a variety of sheet-metal forming manufacturing processes, such as punching using a machine press or stamping press, blanking, embossing, bending, flanging, and coining. This could be a single stage operation where every stroke of the press produce the desired form on the sheet metal part, or could occur through a series of stages. The process is usually carried out on sheet metal, but can also be used on other materials, such as polystyrene.

A radio frequency scanner utilizes radio frequency signals to send and receive data to and from RFID cards during the scanning process. When those signals cannot be transmitted to or from the RFID cards, the RFID cards cannot be scanned. The mechanism that prevents transmission of radio frequency signals through the material of the device 100 is Gauss' law, which mandates that a conducting sphere does not allow electrical fields to be propagated into or out of the sphere. Surrounding, or partially surrounding, an RFID card with the conducting material of the device 100 has the same or similar effect as surrounding the RFID card with a conducting sphere, i.e., radio frequency signals cannot be transmitted through the device 100, thereby preventing scanning of the RFID card by a scanner.

Preferably, the size of each device 100 is substantially the size of a credit card, which is substantially 3 and ⅜ inch, by 2 and ⅛ inch by 0.02 inch. Preferably, the size of each device 100 is substantially a size that allows for insertion into a card slot or pocket, such as the pockets found in a wallet (see FIG. 2).

Experimental results from testing of the present invention are hereby provided. Testing occurred in August 2011 on a device 100 substantially the size of a credit card, i.e., 3 and ⅜ inch, by 2 and ⅛ inch by 0.02 inch. A commercially available RFID scanner operating at 13.56 MHz was used at a distance of 50 mm from the device 100. In each test, a different configuration of devices together with RFID cards in a wallet was used (see FIG. 2). All of the following configurations resulted in no reading of any data from any of the RFID cards in the configuration: 1) a single device 100 in front of a single RFID card in a set of pockets similar to the wallet of FIG. 2; 2) a configuration wherein devices 100 were placed on either end of a stack of cards including one or two RFID cards in a set of pockets similar to the wallet of FIG. 2; 3) a configuration wherein devices 100 were placed on either end of a stack of cards including one or two RFID cards, and wherein a third device 100 was inserted in the middle of the pack of cards, wherein the entire set of devices 100 and RFID cards was placed in a set of pockets similar to the wallet of FIG. 2.

FIG. 1A presents a perspective view of credit cards placed between two scanner resistant devices in an embodiment. A first three layer scanner resistant device 100 is shown having a reading lens 101 loaded into a holder device 102 such that a group of credit cards are disposed between it and a second three layer scanner resistant device 103. This second scanner resistant device 103 does not have a reading lens integral therewith but comprises a simple planar body having the aforementioned three layers; namely, two outer plastic layers and a central metallic layer integrally formed and connected along the edges of the two outer plastic layers that encapsulate the metallic layer therein. The first scanner resistant device 100 has a similar configuration of layers with the addition of a reading lens disposed thereon.

FIG. 1B presents a front elevation view of credit cards placed between two scanner resistant devices in an embodiment. This view shows the disposition of the credit cards as would be expected in a typical wallet. The first scanner resistant device 100 is placed in the front whilst each of the rest of the credit cards are placed one after the other arranged in a hypothetical wallet configuration until the second scanner resistant device 103 completes the system in the rear position. This view also shows the reading lens 101 and its associated holder device integral with the first scanner resistant device 100.

FIG. 2 presents a front cross section view of a wallet having credit cards placed between two scanner resistant devices in an embodiment. The wallet 109 has various pockets arranged vertically up two side wings. The left wing in the drawing shows the disposition of the credit cards as would be expected in a typical wallet 109 having several pockets 110. The first scanner resistant device 100 is placed in the front first pocket whilst each of the rest of the credit cards are placed one after the other in a subsequent pocket 110 arranged in wallet 109 until the second scanner resistant device 103 completes the system in the rear pocket position. This view also shows the reading lens 101 and its associated holder device integral with the first scanner resistant device 100.

FIG. 3 presents a cross section perspective view of the three layer structure of a first scanner resistant device in an embodiment. The first scanner resistant device is a three layer device having two plastic outer layers 104, 106 attached together along their respective peripheral edges and having an inner metallic layer 105 sandwiched there between. As discussed previously, the integration of the two outer layers of plastic (ABS, PVC, PET etcetera) is via heat treatment, lamination, adhesive or similar forms of attachments for these types of materials. A U shaped holder device 102 is integrally disposed atop the plastic layer 106 permitting easy access to the lens to be loaded therein; the open end of the holder device 102 is close to or adjacent a transverse edge of the card thereby facilitating easy gripping of the reading lens 101. Finally, the structure of this plastic layer 106 has a concave curvature inwardly arranged towards the reading lens 101 that has a matching peripheral surface for maintaining it therein.

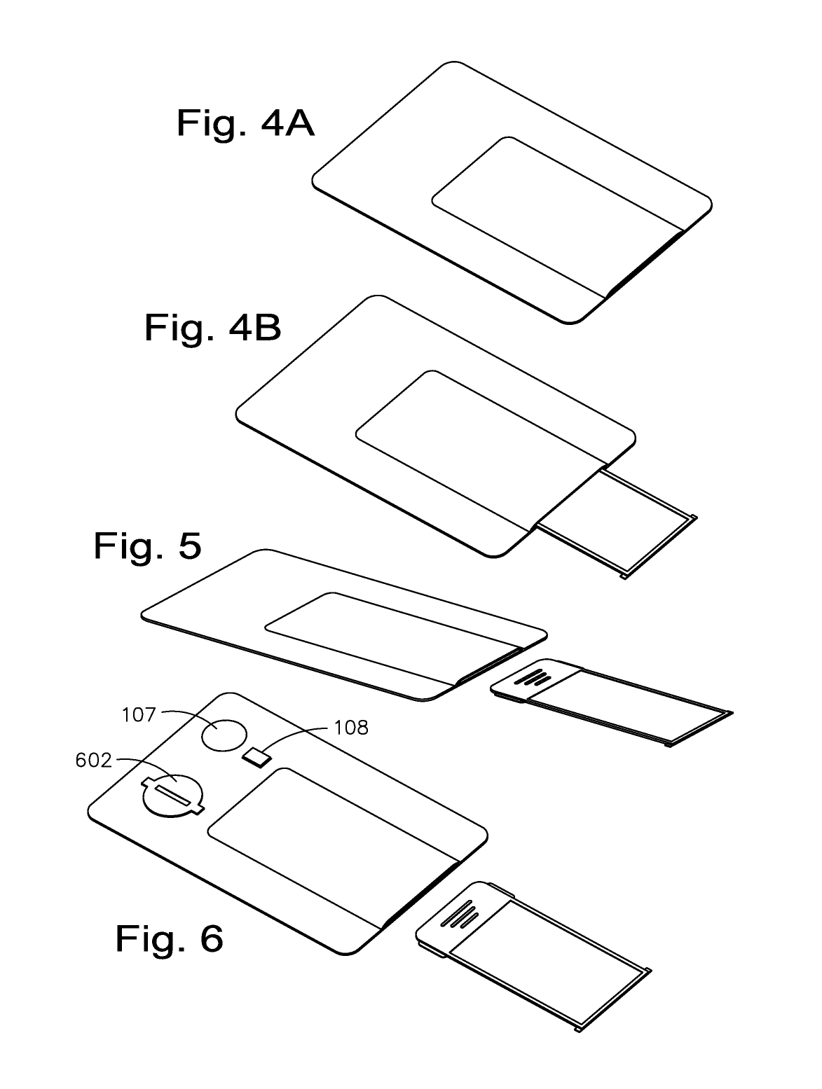

FIG. 4A presents a front elevation view of a reading lens retracted into its built in holder of the first scanner resistant device in an embodiment. FIG. 4B presents a front elevation view of a reading lens being deployed out of its built in holder of the scanner resistant device in an embodiment.

FIG. 5 presents a front elevation view of a reading lens being deployed out of its built in holder of the first scanner resistant device in an embodiment; this view particularly shows the curved surface of the holder. The reading lens 102 is typically about ⅞ inch wide and is typically operationally deployable to a portion 1⅝ inch of its overall length.

FIG. 6 presents a front elevation view of a reading lens being deployed out of its built in holder of the first scanner resistant device in an embodiment; this view also shows a built in button for actuating LED lights also built into the scanner resistant device. A plastic button 107 is integral with a side of the scanner resistant device 100; the button 107 is disposed on the scanner resistant device opposite the opening of the holder device 102 so as not to interfere with the use of the reading lens 101 loaded therein. Additionally, one or more LED lights 108 are integrated into the body of the first scanner resistant device 100. The LED lights 108 are in series electric communication with a battery and a plastic button having two electrical contacts (one to the battery, one to the LED light(s) and from the LED light(s) back to the battery) thereon for forming a simple wired circuit. This is accomplished through battery (not shown), wiring (not shown) being embedded in and integral with the first scanner resistant device's outer layer 106. Care is taken at manufacture that the central layer 105 does not make contact with this wiring as this would disrupt circuit operation. FIG. 6 also shows a battery cover or door 602 which acts like a door to provide access to a battery within the device 100, wherein the battery provides power to the LED light.

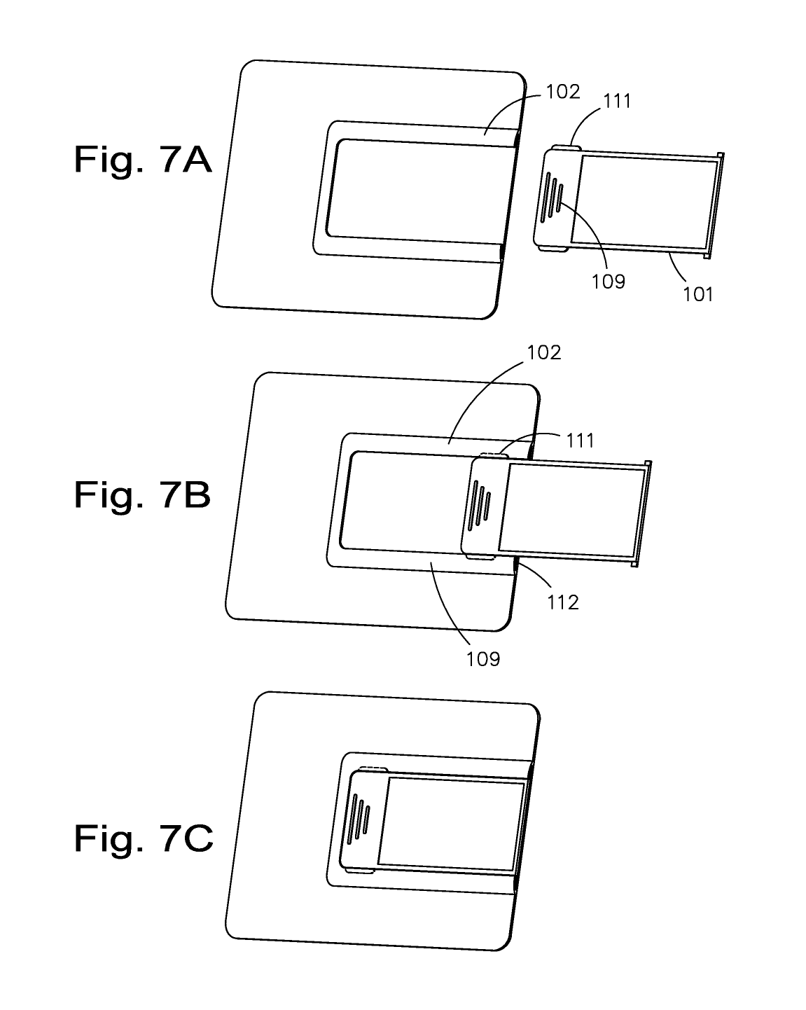

FIG. 7A presents the reading lens device fully removed from the scanner resistant device in an embodiment. The PC reading lens 101 is an oblong piece of material having a reading portion 101A and a movement portion 101B. The reading portion 101A has a clear PC material for expanding the view of small text. The movement portion 101B has one or more thumb assistance protrusions 109 that extend upwards out of one side thereof for assisting a user in sliding or ejecting the reading lens 101 therefrom. Additionally, the movement portion 101B has top and bottom locking protrusions 111 disposed opposite one another; these are designed to engage corresponding inwardly directed raised portions 112 at or near the end of the holding device 102 (on the concave side inwardly disposed) thereby forbidding the complete extraction of the reading lens 101 unless a significant amount of force is applied. This has the intended effect of permitting use of the lens 101 without concerning oneself with it falling out.

A similar dual inwardly directed set of raised protrusions 113 (not shown) is arranged on the opposite side of the holder device close to the bottom short leg of its U shape and as before on the inner surface of the holder device 102. Here it should be understood that this set of raised protrusions 113 is not as pronounced as the one at the opposite end of the holder device 102 as this is only meant to slightly lock it place for ordinary use. FIG. 7B presents the reading lens partially deployed from or partially retracted into the scanner resistant device in an embodiment. FIG. 7C presents the reading lens device fully retracted into the scanner resistant device.

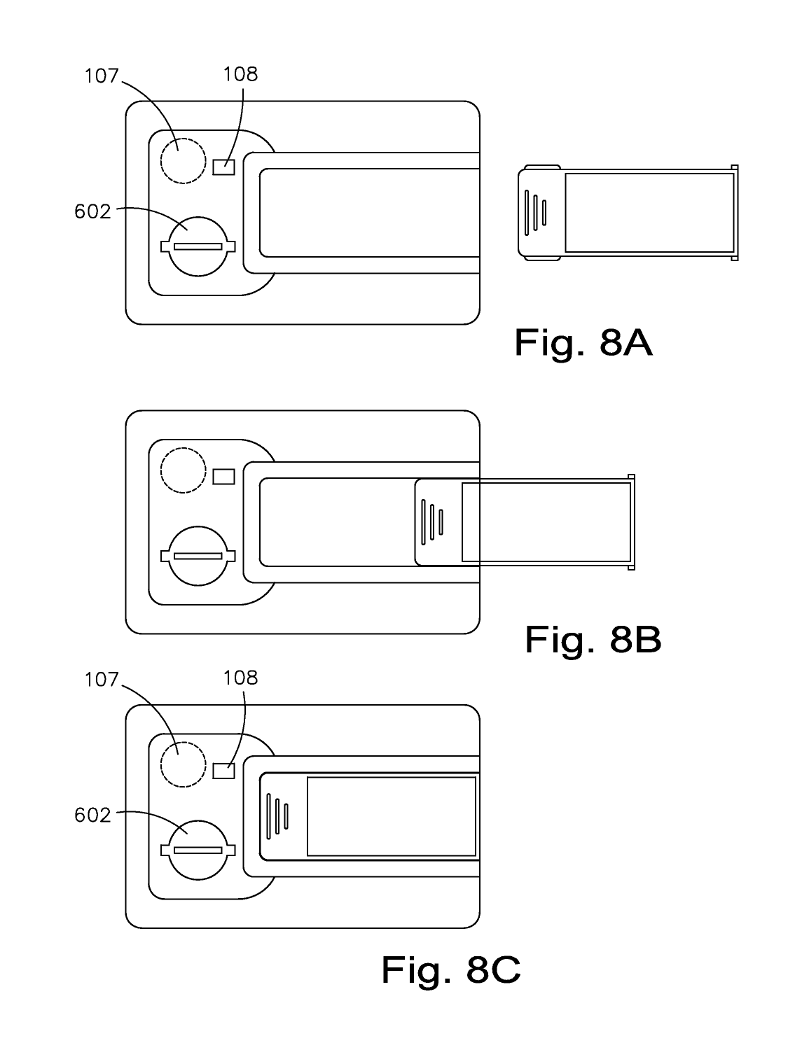

FIG. 8A presents the reading lens device fully removed from the first scanner resistant device in an embodiment having a plastic button and LED light(s) thereon. FIG. 8B presents the reading lens device partially deployed from or partially retracted into the first scanner resistant device in an embodiment having a plastic button and LED light(s) thereon. FIG. 8C presents the reading lens device fully retracted into the first scanner resistant device in an embodiment having a plastic button and LED light(s) thereon

Although specific embodiments have been disclosed, those having ordinary skill in the art will understand that changes can be made to the specific embodiments without departing from the spirit and scope of the invention. The scope of the invention is not to be restricted, therefore, to the specific embodiments. Furthermore, it is intended that the appended claims cover any and all such applications, modifications, and embodiments within the scope of the invention.

We claim:

1. A device for preventing radio frequency scanning of a card comprising:
a first planar element sized for fitting within a card slot of a personal carrying accessory wherein the planar element has
a reading lens moveably attached thereto.

2. The device for preventing radio frequency scanning of a card of claim 1, further comprising:
a metallic material attached to a surface of the planar element.

3. The device for preventing radio frequency scanning of a card of claim 1, further comprising:
a holder device integrated with a surface of the planar element.

4. The device for preventing radio frequency scanning of a card of claim 3, wherein the holder device has a U shape.

5. The device for preventing radio frequency scanning of a card of claim 3, wherein the holder device further comprises:
a concave surface.

6. The device for preventing radio frequency scanning of a card of claim 3, wherein the holder device further comprises:
a removal prevention mechanism cooperating with the reading lens.

7. The device for preventing radio frequency scanning of a card of claim 3, wherein the holder device further comprises:
a sliding slowing mechanism cooperating with the reading lens.

8. The device for preventing radio frequency scanning of a card of claim 1, further comprising:
a light source integrally attached to the planar element.

9. The device for preventing radio frequency scanning of a card of claim 8, wherein the light source further comprises an LED.

10. The device for preventing radio frequency scanning of a card of claim 8, further comprising:
a battery integrally attached with the planar element and in electronic communication with the light source.

11. The device for preventing radio frequency scanning of a card of claim 10, further comprising:
a button integrally attached with the planar element and in electronic communication with the light source and the battery for permitting actuation of the light source through the use of the button.

12. The device for preventing radio frequency scanning of a card of claim 1, further comprising:
a second planar element sized for fitting within a card slot of a personal carrying accessory wherein the planar element is attached to the first planar element.

13. The device for preventing radio frequency scanning of a card of claim 12, further comprising:
a metallic material disposed between and integrally formed within the first and second planar elements.

14. A method for preventing radio frequency scanning of a card, comprising:
placing a first planar element within a first card slot of a personal carrying case having a plurality of vertically arranged card slots such that the first planar element is located substantially on a front side of the personal carrying case card slot, wherein the planar element is sized for fitting within a card slot of the personal carrying accessory, wherein the planar element is composed of an uncharged, conductive material and wherein the planar element inhibits the transmission of radio frequency signals; and
placing a second planar element within a second card slot of the personal carrying case such that the second planar element is located substantially on a rear side of the plurality of card slots, and wherein the second planar element shares the same characteristics of the first planar element.

15. The method for preventing radio frequency scanning of a card of claim 14, further comprising:
a third planar element integrated with the first planar element wherein the third planar element has a reading lens holder integrally formed thereon.

16. The method for preventing radio frequency scanning of a card of claim 14, further comprising:
a third planar element integrated with the first planar element wherein the third planar element has a light source integrally formed thereon.

17. The method for preventing radio frequency scanning of a card of claim 16, further comprising:
a battery integrally attached with the third planar element and in electronic communication with the light source.

18. The method for preventing radio frequency scanning of a card of claim 17, further comprising:
a button integrally attached with the third planar element and in electronic communication with the light source and the battery for permitting actuation of the light source through the use of the button.

19. A device for preventing radio frequency scanning of a card comprising:
a first planar element sized for fitting within a card slot of a personal carrying accessory wherein the planar element has
a light source integrally associated with the first planar element.

20. The device for preventing radio frequency scanning of claim 19, further comprising:
a reading lens holder device.
